(19) United States
(12) Patent Application Publication
(10) Pub. No.: US 2025/0105006 A1
(43) Pub. Date: Mar. 27, 2025

(54) PROCESS FOR SYNTHESIS OF MONOLAYER TRANSITION METAL DICHALOCOGENIDE

(71) Applicant: INDIAN INSTITUTE OF SCIENCE EDUCATION AND RESEARCH, PUNE (IISER PUNE), Pune, Maharashtra (IN)

(72) Inventors: Gokul M. A, Kerala (IN); Atikur RAHMAN, Maharashtra (IN)

(21) Appl. No.: 18/730,209

(22) PCT Filed: Feb. 1, 2023
(86) PCT No.: PCT/IB2023/050869

§ 371 Date: Jul. 18, 2024

(30) Foreign Application Priority Data
Feb. 1, 2022 (IN) 202221005450

(51) Int. Cl. H01L 21/02; C23C 16/02; C23C 16/30; C23C 16/52

(52) U.S. Cl. CPC H01L 21/02568; C23C 16/0272; C23C 16/305; C23C 16/52; H01L 21/02175; H01L 21/0259; H01L 21/0262

(57) ABSTRACT

The present disclosure relates to a process for preparation of reliable conformal growth of transition metal dichalocogenide (TMD) monolayers by using metal silicates as a growth promoter that improves the tolerance of growth of TMD monolayers films while maintaining good optoelectronic properties of the film in atmospheric pressure chemical vapour deposition (APCVD).

### CROSS-REFERENCE TO RELATED APPLICATIONS

This application is the U.S. National Stage entry of International Application No. PCT/IB2023/050869, filed on Feb. 1, 2023, which, in turn, claims priority to Indian Patent Application number 202221005450, filed on Feb. 1, 2022, both of which are hereby incorporated herein by reference in their entireties for all purposes.

### FIELD OF THE INVENTION

The present disclosure relates to the technical field of semiconductors. In particular, the present disclosure relates to a process for the preparation of reliable synthesis of transition metal dichalocogenide (TMD) monolayers by using metal silicates as a growth promoter that improves the tolerance of growth of TMD monolayers films while maintaining good optoelectronic properties of the film in atmospheric pressure chemical vapour deposition (APCVD).

### BACKGROUND OF THE INVENTION

Background description includes information that may be useful in understanding the present invention. It is not an admission that any of the information provided herein is prior art or relevant to the presently claimed invention, or that any publication specifically or implicitly referenced is prior art.

TMD monolayers offer rich physics at their monolayer regime and can potentially revolutionize the semiconducting industry by providing new degrees of control. However, a massive hurdle to achieve this goal is the reliable large scale synthesis of monolayers of these materials.

The standard technologies for the synthesis of monolayer TMDs include Atomic Layer Deposition (ALD), Metal Organic Chemical Vapor Deposition (MOCVD) and APCVD. Techniques like ALD usually result in polycrystalline films and the film quality is not great, techniques like MOCVD on the other hand are too complex and are expensive when it comes to implementation. APCVD on the other hand is very sensitive to subtle changes in parameters. People generally use growth promoters to overcome this limitation of the APCVD system. But most growth promoters have limited effectiveness or they are hard to procure. Though CVD is regarded by most as the best candidate to achieve this goal the technique is very sensitive to minute changes in growth condition which makes reproducible, large scale synthesis of these materials a huge challenge.

There is thus a need in the art to provide a new, improved and highly efficient process for synthesis of monolayer TMDs. The present disclosure satisfies the existing needs, as well as others, and generally overcomes the deficiencies found in the prior art.

### OBJECTS OF THE INVENTION

Objects of the present disclosure is to provide an efficient process for synthesis of monolayer TMDs onto substrates.

An object of the present disclosure is to provide a reliable process for synthesis of monolayer TMDs, that improves the tolerance of growth of TMD monolayers films to changes in growth parameters in APCVD, while maintaining good optoelectronic properties.

Another object of the present disclosure is to provide a reliable process for synthesis of monolayer TMDs using sodium silicate, also known as water glass (WG), as growth promoter.

Another object of the present disclosure is to provide a technique to achieve conformal growth of monolayer transition metal dichalocogenide films on textured substrates for novel device application.

Yet another object of the present disclosure is to provide monolayer transition metal dichalocogenide films having good opto-electronic properties.

### SUMMARY OF THE INVENTION

The foregoing and other objects are attained by the present disclosure, which in an aspect provides a process for synthesis of monolayer TMDs using metal silicates as a growth promoter to increase the tolerance of these materials to changes in the growth parameter.

In one aspect, the present disclosure provides a process for reliable synthesis of transition metal dichalocogenide (TMD) monolayers using a single zone furnace, said process comprises the steps of:
(a) spin coating a dilute solution of a growth promoter in water, onto a substrate of interest at 4000 r.p.m, wherein sodium silicate is a growth promoter of transition metal dichalocogenide (TMD) monolayers;
(b) loading the sodium silicate-coated substrate along with the transition metal precursors and chalcogens like elemental sulphur or selenium into the chemical vapour deposition (CVD) chamber;
(c) providing inert gases selected from N2, Ar, H2, or combinations thereof as carrier gases for transition metal dichalocogenide synthesis;
(d) heating the CVD chamber to the desired reaction temperature and holding the reaction temperature for the synthesis of transition metal dichalocogenide (TMD), which is deposited as TMD monolayers over the sodium silicate-coated substrate; and
(e) cooling the CVD chamber to room temperature to obtain the sodium silicate-coated substrate comprising the TMD monolayers.

In an embodiment of the present disclosure, the growth promoter is sodium silicate used at least at a concentration ranging from 0.05% to 50%. For example, at least 0.01%, at least 0.2%, at least 0.5%, at least 1%, at least 5%, at least 10%, at least 20%, or at least 50%. Preferably 0.5%.

In an embodiment of the present disclosure, the substrate is substrate selected from the group consisting of quartz, silicon, doped or undoped, or an active layer of a silicon-on-insulator (SOI) substrate. The substrate can also be smooth or textured.

In an aspect of the present disclosure, the transition metal precursors are selected from the group consisting of tungsten (W), and molybdenum (Mo).

In an aspect of the present disclosure, the chalcogens are selected from the group consisting of sulphur, selenium, or combinations thereof.

In an aspect of the present disclosure, the TMD monolayers comprise MoS₂, MoSe₂, WS₂, WSe₂, or a combination thereof.

In an aspect of the present disclosure, the carrier gas for the synthesis of MoS₂ and WS₂ is Argon, Nitrogen or their mixture; and wherein the carrier gas for the synthesis of MoSe₂ and WSe₂ is Argon and 10% hydrogen mixture.

In an aspect of the present disclosure, the chalcogen can be heated separately and is controlled in the range of 150° C. to 300° C. for the supply of chalcogen during the reaction.

In an aspect of the present disclosure, the heating for chalcogen is set at 200° C. for sulphur and 300° C. for selenium, wherein the heating is turned on 5 min before the target temperature is attained and is turned off after the reaction.

In an aspect of the present disclosure, the deposition of the TMD monolayers on the surface of the substrate is carried out at desired reaction temperature of 500° C. to 900° C., wherein the temperature is ramped up at a rate of 5° C./min till the reaction temperature is attained and maintained for 10 min to get scattered triangles and 20 min to get continuous films.

In an aspect of the present disclosure, the process further comprises the step of flushing the tubes of a single zone furnace with Argon gas at 500 sccm for 5 min and maintaining a constant flow rate of 30 sccm for MoS₂ or WS₂ deposition and 200 sccm for WSe₂ monolayer deposition throughout the reaction.

In another aspect of the present disclosure, the sodium silicate-coated substrate is positioned in such a way that sodium silicate-coated smooth side/textured side facing down in the quartz tube of the single zone furnace for depositing monolayers of WS₂ or WSe₂ synthesized at 850 deg C.

In yet another aspect of the present disclosure, the sodium silicate-coated substrate is positioned in such a way that sodium silicate-coated smooth side/textured side facing down in the quartz tube of the single zone furnace for depositing monolayers of MoS₂ synthesized at 500 deg C. and silicate-coated smooth side facing up for depositing monolayers of MoS₂ synthesized at 600 deg C.

In yet another aspect of the present disclosure, the sodium silicate-coated substrate is positioned in such a way that sodium silicate-coated smooth side/textured side facing up in a separate boat away from the MoO₃ precursor in the quartz tube of the single zone furnace for depositing monolayers of MoS₂/MoSe₂ synthesized at 700 deg C. and above.

In an embodiment of the present disclosure, the CVD can be atmospheric pressure chemical vapour deposition.

Various objects, features, aspects and advantages of the inventive subject matter will become more apparent from the following detailed description of preferred embodiments.

### BRIEF DESCRIPTION OF THE FIGURES

FIG. 1 schematically shows a process of manufacturing TMD monolayers in a typical CVD configuration.

FIG. 2 represents comparison of growth of MoS₂ using NaCl and Sodium-silicate (a), schematic of the growth showing good growth in Sodium-silicate coated substrate (indicated as WG coated) and little to no growth in the NaCl coated substrate. (b) is the optical microscope image of the substrate coated with Sodium-silicate as a growth promoter after the growth and (c) is the optical microscope image of the substrate coated with NaCl as a growth promoter after the growth. The scale bars are 50 μm. It is clear that under the same condition Sodium-silicate clearly outperforms NaCl. (d) is the TGA of mixtures of NaCl+MoO₃ and Sodium-silicate+MoO₃. The TGA of the NaCl+MoO; mixture starts only after 380° C. whereas the Sodium-silicate+MoO₃ mixture starts to slowly evaporate even at temperatures as low as 100° C. suggesting a higher reactivity for the mixture. The slow reduction in the weight of Sodium-silicate+MoO₃ shows a steady reaction.

FIG. 3 represents measuring electrical properties of monolayer MoS₂ (a), The dark and light current from a MoS₂ device. There is a good photocurrent generation, above 5 μA, in the device. The light source is a 405 nm LED of 12 mW/cm² intensity. (b) depicts the transient photoresponse of the device in the presence of 405 nm LED illumination. (c) is the source-drain voltage sweep of the device at different gate voltage. (d) is the source-drain current versus back gate voltage sweep of a MoS₂ device used to measure the mobility of the device. (e) and (f) are the mobility statistics of devices fabricated on monolayer MoS₂ synthesized with NaCl and WG respectively.

FIG. 4 photograph of a continuous large area monolayer TMD grown on a one-inch Quartz substrate kept along with an uncoated Quartz substrate for comparison.

FIG. 5 represents measuring electrical properties of the continuous film (a), the photograph of the measurement system measuring a centimeter-long MoS₂ monolayer film for its electrical property. The optical microscope image in (b) depicts a clean monolayer with only a small area of uncoated substrate. The scale bar is 50 μm. (c) is the schematic showing the entire measurement system and in the inset is the photograph of the continuous MoS₂ film that is being measured.

FIG. 6 shows the optical microscope images of MoS₂ grown on substrates coated with sodium silicate of various concentration (0.05% to 50%). Although all concentrations yielded monolayers concentration of 0.5% gave good coverage and did not alter the colour of the substrate indicating a very thin uniform coating. Higher concentrations effect the substrate color as coating layer becomes thicker. At lower concentration the growth is towards the edges indicating a sub optimal coating thickness at 4000 r.p.m

FIG. 7(a), shows the optical images of monolayer TMD grown on a trenched 300 nm SiO₂ on Si substrate. (b) and (c) are the FESEM images of monolayer TMD grown in (a) at very narrow trenches.

FIGS. 8 (a) and (b) SEM images of TMD monolayers conformally grown on a patterned surface with a sharp structure of radius of curvature of 20 nm, (b) shows the magnified version of the structure with TMD monolayer grown conformally on it. (c) and (d) are FESEM images of TMD monolayers grown on a patterned silicon with little hemishperes making a hexagonal lattice.

FIG. 9 shows the optical characteristic of substrate in FIG. 8 (a): (a) shows the single shot PL image which indicates a clear increase in PL intensity along a line, (b) shows the line scan of intensity along the arrow marked in figure (a). (c) shows the fitted PL spectra at the region of maximum PL intensity, showing a clear increase in the trionic peak intensity.

FIGS. 10 (a) and (b) shows the schematics of PL emission from the substrate and the corresponding mechanism at play.

FIG. 11 shows the optical microscopic images of the different TMDs grown on SiO₂ on Si substrates.

FIG. 12 shows the PL of different monolayer TMDs. The characteristic PL peak differentiates individual TMD and the high PL conforms the monolayer nature of the TMDs as monolayers have a very high PL intensity.

FIGS. 13 (a) and (b) shows the PL image of WS₂ monolayers taken under a florescence microscope. The PL spectra in (c) shows that the PL from monolayer WS₂ is over a 1000 times stronger than the PL from bilayer

FIG. 14 shows the Raman spectra from different monolayer TMDs.

### DETAILED DESCRIPTION OF THE INVENTION

The following is a detailed description of embodiments of the present disclosure. The embodiments are in such detail as to clearly communicate the disclosure. However, the amount of detail offered is not intended to limit the anticipated variations of embodiments: on the contrary, the intention is to cover all modifications, equivalents, and alternatives falling within the spirit and scope of the present disclosure as defined by the appended claims.

Unless the context requires otherwise, throughout the specification which follow, the word “comprise” and variations thereof, such as, “comprises” and “comprising” are to be construed in an open, inclusive sense that is as “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable.

The recitation of ranges of values herein is merely intended to serve as a shorthand method of referring individually to each separate value falling within the range. Unless otherwise indicated herein, each individual value is incorporated into the specification as if it is individually recited herein.

All processes described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

The headings and abstract of the invention provided herein are for convenience only and do not interpret the scope or meaning of the embodiments.

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

It should also be appreciated that the present invention can be implemented in numerous ways, including as a system, a method or a device. In this specification, these implementations, or any other form that the invention may take, may be referred to as processes. In general, the order of the steps of the disclosed processes may be altered within the scope of the invention.

The present disclosure generally relates to a process for preparation of reliable synthesis of transition metal dichalocogenide (TMD) monolayers by using metal silicates as a growth promoter.

In an embodiment, the present invention relates to a present disclosure provides a process for reliable synthesis of transition metal dichalocogenide (TMD) monolayers using a single zone furnace, said process comprises the steps of:
(a) spin coating a dilute solution of a growth promoter in water, onto a substrate of interest at 4000 r.p.m, wherein sodium silicate is a growth promoter of transition metal dichalocogenide (TMD) monolayers;
(b) loading the sodium silicate-coated substrate along with the transition metal precursors and chalcogens like elemental sulphur or selenium into the chemical vapour deposition (CVD) chamber;
(c) providing inert gases selected from N2, Ar, H2, or combinations thereof as carrier gases for transition metal dichalocogenide synthesis;
(d) heating the CVD chamber to the desired reaction temperature and holding the reaction temperature for the synthesis of transition metal dichalocogenide (TMD), which is deposited as TMD monolayers over the sodium silicate-coated substrate; and
(e) cooling the CVD chamber to room temperature to obtain the sodium silicate-coated substrate comprising the TMD monolayers.

In an embodiment of the present disclosure, the growth promoter is sodium silicate used at least at a concentration ranging from 0.05% to 50.0%. For example, at least 0.1%, at least 0.2%, at least 0.3%, at least 0.4%, at least 0.5%, at least 0.6%, at least 0.7%, at least 0.8%, at least 0.9%, or at least 1.0%. Preferably 0.5% for an r.p.m of 4000. The concentration may vary for different r.p.m

In an embodiment of the present disclosure, the precursors can be delivered by vapor phase during the reaction.

In an embodiment of the present disclosure, the chalcogen is selected from sulphur or selenium or combinations thereof.

In an embodiment the present disclosure, the substrate of interest is semiconductor substrate selected from the group consisting of silicon, doped or undoped, or an active layer of a silicon-on-insulator (SOI) substrate or Quartz substrate. The substrate of interest may include a Group IV semiconductor material layer (e.g., Si, Ge, SiGe, GeSn, etc.), a Group III-V semiconductor material layer, or a Group II-VI semiconductor material layer, and the like. The substrate can also be any arbitrary materials like sapphire, mica, quartz etc., given it can withstand the temperature.

In an embodiment the present disclosure, the TMD monolayers comprise MoS₂. WS₂, WSe₂, MoSe₂, MoTe₂, WTe₂, or a combination thereof.

In another embodiment of the present disclosure, the thickness of the TMD monolayer is in the range of 0.7 nm to 1 μm.

In an embodiment of the present disclosure, the deposition of the transition metal dichalocogenide on the surface of the substrate is carried out at a temperature in the range of 500° C. to 900° C. In another embodiment of the present disclosure, the temperature range depends on the precursors used and the TMD to be synthesized.

In an embodiment of the present disclosure, the precursor and the substrate is present in an amount from 10 mg to 500 mg (depending on TMD grown, temperature of synthesis and precursors used).

In an embodiment of the present disclosure, the chalcogen can be heated separately and is controlled in the range of 150° C. to 300° C. for the supply of chalcogen during the reaction.

In an embodiment of the present disclosure, the heating for chalcogen is set at 200° C. for sulphur and 300° C. for selenium, wherein the heating is turned on 5 min before the target temperature is attained and is turned off after the reaction.

In an embodiment of the present disclosure, the deposition of the transition metal dichalocogenide monolayers on the surface of the substrate is carried out at desired reaction temperature of 500° C. to 900° C., wherein the temperature is ramped up at a rate of 5° C./min till the reaction temperature is attained and maintained for 10 min to get scattered triangles and 20 min to get continuous films.

In an embodiment of the present disclosure, the process further comprises the step of flushing the tubes of single zone furnace with Argon gas at 500 sccm for 5 min and maintaining a constant flow rate of flow rate of 30 sccm for MoS₂ or WS₂ deposition and 200 sccm for WSe₂ monolayer deposition throughout the reaction.

In an embodiment of the present disclosure, the sodium silicate-coated substrate is positioned in such a way that sodium silicate-coated smooth side/textured side facing down in the quartz tube of the single zone furnace for depositing monolayers of WS₂ or WSe₂ synthesized at 850 deg C.

In an embodiment of the present disclosure, the sodium silicate-coated substrate is positioned in such a way that sodium silicate-coated smooth side/textured side facing down in the quartz tube of the single zone furnace for depositing monolayers of MoS₂ synthesized at 500 deg C. and silicate-coated smooth side facing up for depositing monolayers of MoS₂ synthesized at 600 deg C.

### EXAMPLES

The present disclosure is further explained in the form of following examples. However, it is to be understood that the foregoing examples are merely illustrative and are not to be taken as limitations upon the scope of the invention. Various changes and modifications to the disclosed embodiments will be apparent to those skilled in the art. Such changes and modifications may be made without departing from the scope of the invention.

### Example 1: Manufacturing TMD Monolayers in a Typical CVD Configuration

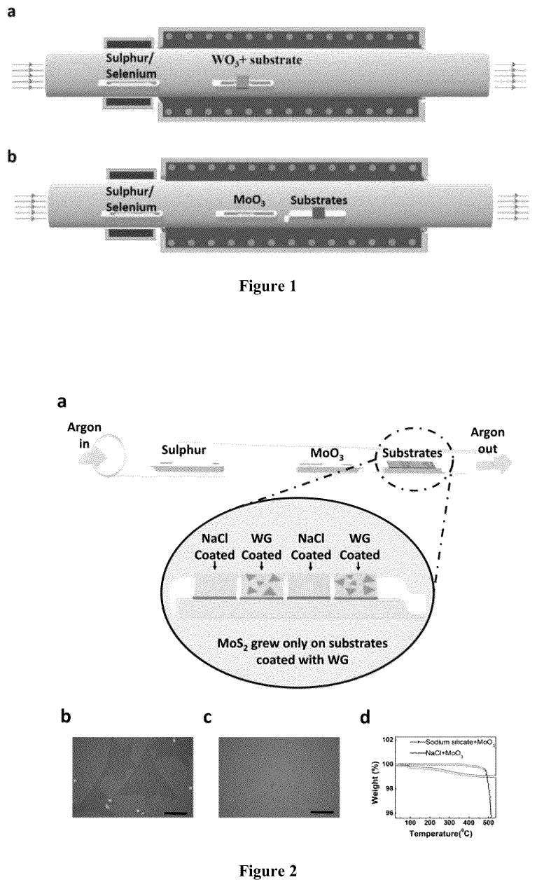

The CVD growth was carried out in a quartz tube of 3.5 cm diameter, in a single zone furnace. There is a separate heater just outside the furnace attached to the tube to heat the chalcogens separately. Argon/Nitrogen gas is used as a carrier gas for the synthesis of MoS₂ and WS₂. Argon hydrogen mixture (10% H2) was used to synthesise WSe₂. The alumina boat containing the chalcogen is placed just outside the furnace where we have attached a separate heater as shown in FIG. 1. The boat containing the transition metal precursor is kept 15 cm away, downstream, from the boat containing the chalcogen as shown in FIG. 1 (a). For synthesising WS₂ and WSe₂ as well as MoS₂ at temperatures lower than 700° C., configuration ‘a’ in FIG. 1 was used. For WS₂, WSe₂ (both synthesised at 850° C.) and MoS₂ (synthesised at 500° C.) the substrate was kept with SiO₂ coated smooth side facing down and for MoS₂ synthesised at 600° C. the SiO₂ coated side was facing up. The change in position was to compensate for the low vaporisation of the precursor at lower temperature. For most of the study on MoS₂ growth at 700° C. configuration ‘b’ in FIG. 1 was used where the substrates were kept facing up on a separate boat 2 cm from the boat containing the transition metal precursor. Initially, the tubes were flushed with Argon gas at 500 sccm for 5 min and then the flow was brought down and maintained at a constant value throughout the reaction. The flow rate for MoS₂ and WS₂ was 30 sccm and for WSe₂ was 200 sccm. The furnace was ramped up at a rate of 5° C./min till the reaction temperature is attained and maintained for 10 min or less to get scattered triangles and 20 min to get continuous films. The heater for chalcogen was set at 200° C. for sulphur and 300° C. for selenium. This heater was turned on 5 min before the target temperature is attained and is turned off after the reaction. The entire set up is allowed to cool down naturally and the samples are taken out after it cools down to room temperature.

### Example 2: Comparison of the Effectiveness of Sodium Silicate and NaCl on Growth of MoS2 Monolayers Under the Same Conditions

To check the effectiveness of using sodium silicate as a growth promoter, we did a comparison of its growth with that of NaCl, a very common growth promoter. We spin-coated 0.5% sodium silicate solution and a 0.001 Molar NaCl solution onto substrates. We reduced the amount of MoO3 to 10 mg, to reduce the precursor concentration during the reaction, and the reaction time was set for 10 min at 700 0C. To ensure that the condition for the growth is similar we kept substrates coated with sodium silicate and salt alternatively on a separate boat as shown in FIG. 2a. After the reaction that was carried out for 10 minutes, good growth was observed in the sodium-silicate-coated substrate and little to no growth was observed in the NaCl-coated substrate. This demonstrated that sodium silicate is a much more efficient growth promoter than NaCl. We did a Thermo-gravimetric analysis (TGA) on NaCl mixed with MoO3 and compared it with dry WG powder mixed with MoO3. As can be seen in FIG. 2d, the WG mixture shows a steady decrease in its mass even at temperatures as low as 100 0C, whereas in the NaCl mixture no weight loss was observed till 380 0C. It is clear from the TGA that the reaction of WG with MoO3 happens more readily than NaCl even at lower temperatures.

### Example 3: Comparison of the Electrical Properties of MoS₂ Monolayers Grown Using Sodium Silicate and NaCl

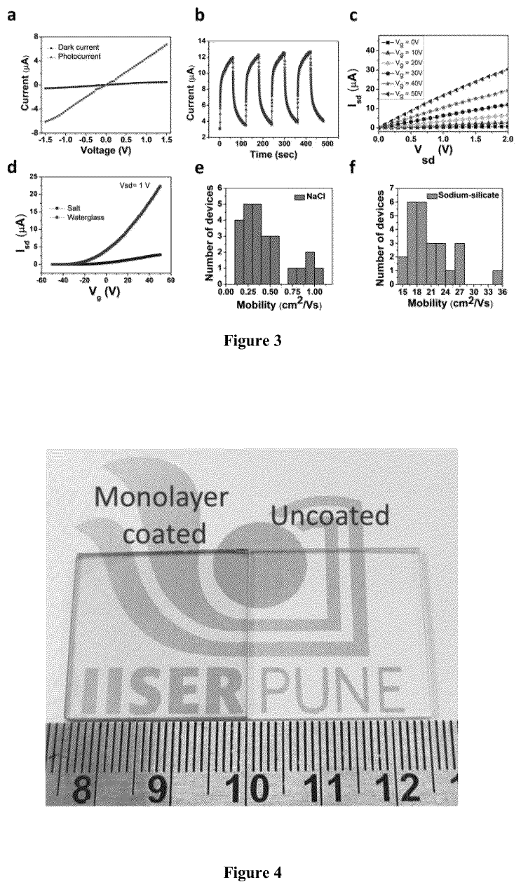

FIG. 3 shows the optoelectric properties of the MoS₂ synthesized using sodium silicate. The devices were made using photolithography followed by thermal vapour deposition of 5 nm Cr followed by 65 nm Au to make active devices on the monolayer film on the 300 nm SiO2 on Si substrate. The SiO₂ was used as a dielectric for field-effect studies such as FETs. The photo response was studied using a 405 nm LED with an intensity of 10 mW/cm² controlled using an Arduino. The dark I-V characteristics, shown in FIG. 3a, of the devices were linear confirming the formation of Ohmic contacts. Devices also show good photo-response with one order change in current when illuminated with a 405 nm Light emitting diode (LED). The time-resolved photo-response, in FIG. 3b, of the device were studied at a bias of IV by illuminating the device using a 405 nm LED at an interval of 1 minute. The Isd-Vsd characteristics showed a linear relationship (FIG. 3c) for a wide voltage range, which also suggest an Ohmic contact at room temperature. A typical source drain current Vs the gate voltage of both devices are given in FIG. 3c. FIG. 3d shows the Isd-Vg plots of the devices made using MoS2 synthesized using NaCl and sodium silicate for comparison. The mobility statistics of devices with sodium silicate and salt are also shown in FIGS. 3e and 3f for comparison. The devices made using MoS2, grown using sodium silicate, exhibited mobility in the range of 15 to 35 cm2 V−1s−1 with an Ion/Ioff ratio of 105 to 106. For comparison, devices were also fabricated on MoS2 synthesized with NaCl (salt). Typical mobility values of devices with samples synthesized using salt were in the range of 0.1 to 1 cm2 V−1s−1. This is far less than those exhibited by samples synthesized using sodium silicate (by more than one order of magnitude). The performance of the samples synthesized using sodium silicate was clearly superior to that of the ones grown using NaCl.

The mobility of the devices were calculated from the linear region of the transfer curve using the equation

$$μ = \frac{{dI}_{ds}}{{dV}_{bg}} \frac{L}{{WC}_{g} {V}_{ds}}$$

Where, L is the channel length, W is the channel width, C_{g} is the gate capacitance per unit area which is given by the relation

$${C}_{g} = \frac{{ε}_{0} {ε}_{r}}{d}$$

where ε0=8.854×10−12 Fm−1, εr for SiO2 is 3.9, and d is the thickness of SiO2, here it is 300 nm.

### Example 4: Growth of Centimeter Scale MoS2 Monolayers Film and its Electrical Conductivity

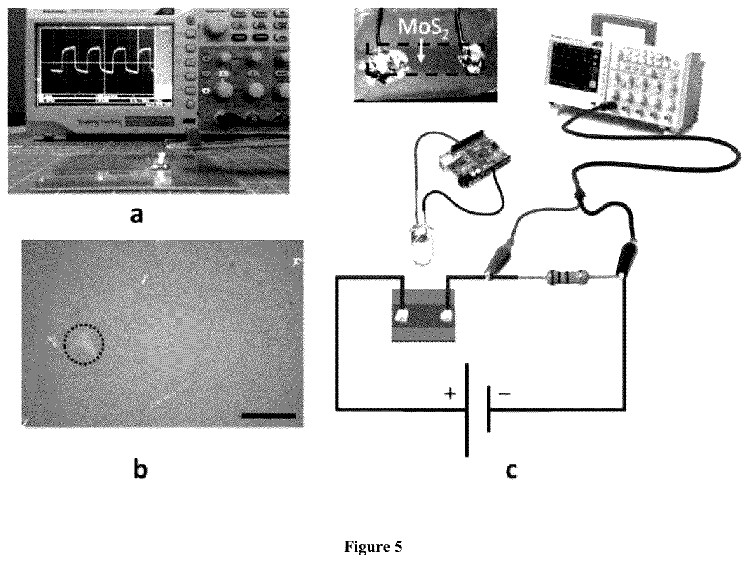

FIG. 4 shows a continuous monolayer MoS2 film grown on a one-inch Quartz plate kept next to a Quartz plate without MoS2 monolayer for demonstrating the scalability of growth. FIG. 5 shows measurement being performed on a continuous monolayer MoS2 film. The device demonstrated that the centimeter size film is electrically continuous and generates a decent photocurrent.

### Example 5: Monolayer TMDs Grown at Varying Concentrations and Conformal Growth of TMD Monolayers

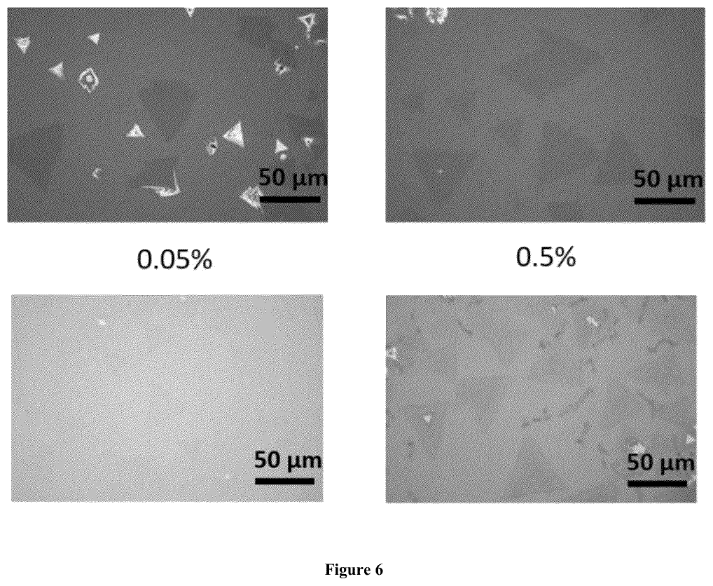

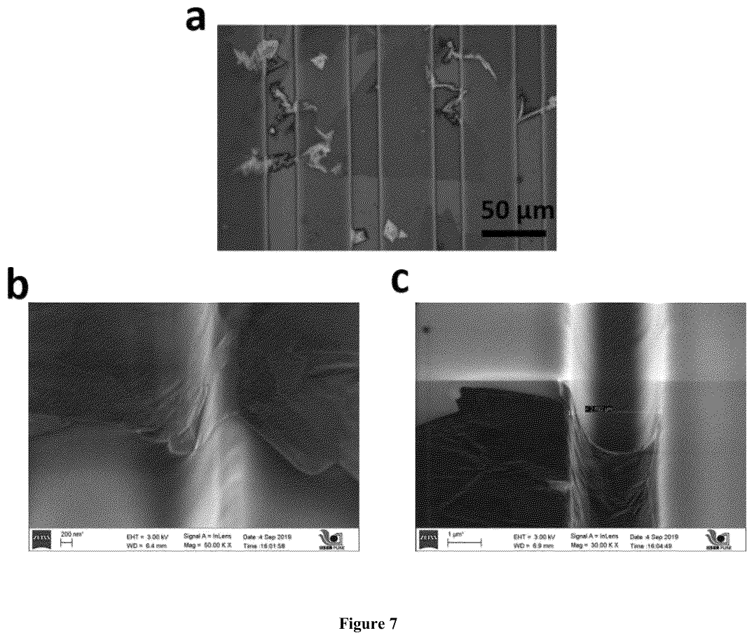

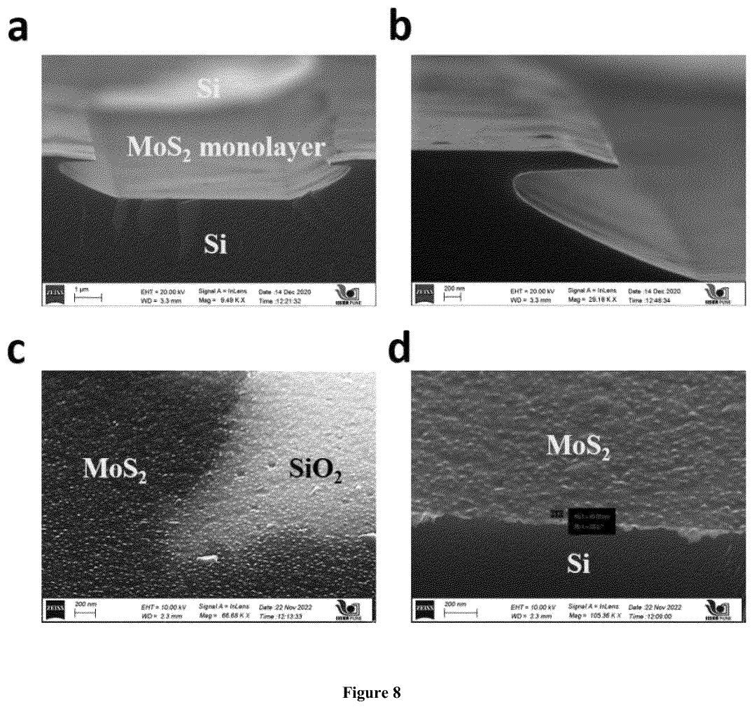

FIG. 6 shows the images of monolayer MoS2 grown on SiO2/Si substrate using different concentrations of sodium silicate from 0.05%-50%. Good growth was observed on all the substrates but the yield was low for substrates that used concentrations less than 0.5% and the substrate color got affected by the thick coating of sodium silicate for concentrations above 5%. FIG. 7 a represents optical images of TMD monolayers grown conformally on a patterned substrate and FIG. 7 ((b) and (c)) shows the FESEM images of coating on trenched SiO2 on Si substrate. FIG. 8 represents SEM images of TMD monolayers conformally grown on a patterned surface: (a) shows the coating on a sharp surface of radius of curvature of 20 nm. (b) magnified image of the textured substrate and figures (c) and (d) shows conformal coating on a textured substrate with small hemispherical lattice covering the entire substrate.

### Example 6: Funnel Effect from Conformally Grown MoS2 Monolayer

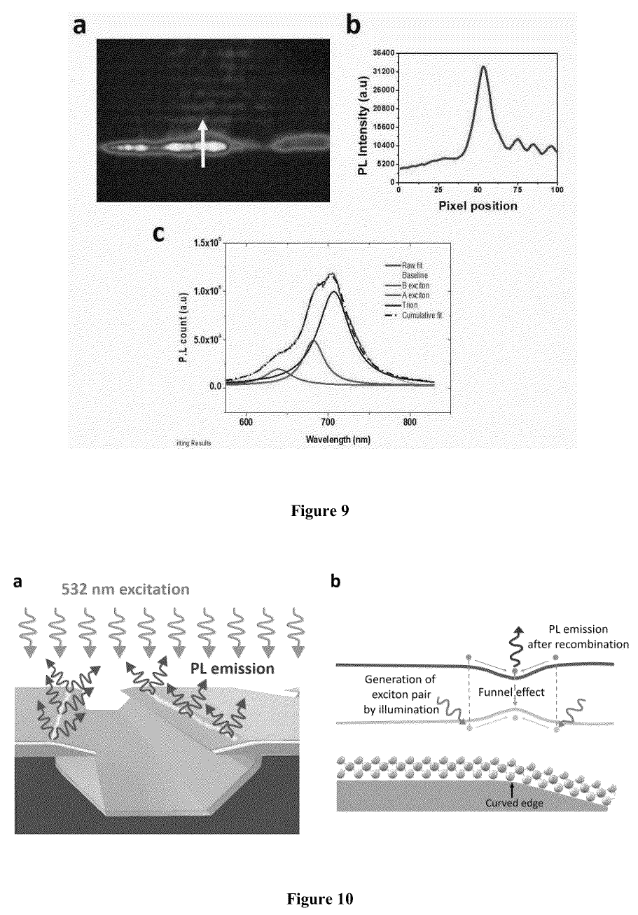

FIG. 9 a shows the single-shot PL image of one of the textured substrate which clearly shows an enhancement in PL intensity at the region of curvature caused by the funnel effect. FIG. 9 b is the graph that shows PL intensity as a function of pixel position along the arrow in FIG. 9 a. FIG. 9 c shows the PL spectra from the region of maximum PL intensity. The PL spectrum from this region clearly shows an enhancement in the trionic peak of the MoS2 PL spectrum, demonstrating the possibility of engineering optical properties of TMDs by conformal coating for novel applications such as photonic crystals. FIG. 10 a and b shows the schematic of emission from the textured substrate and a mechanism of emission respectively.

### Example 7: Characterization of TMDs Monolayers Synthesized Using Sodium Silicate as the Growth Promoter

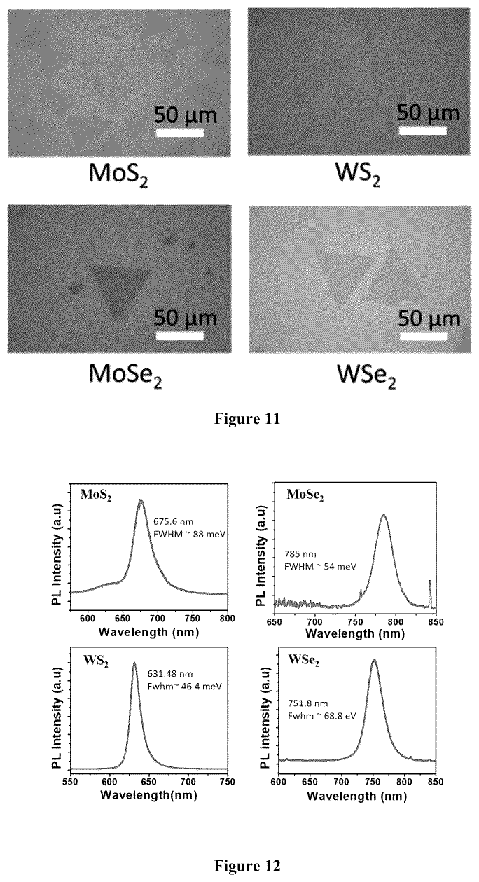

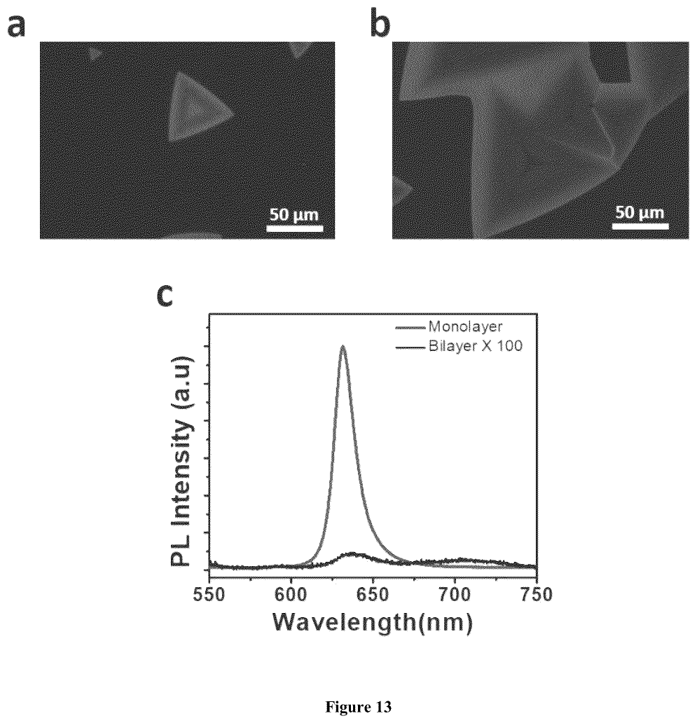

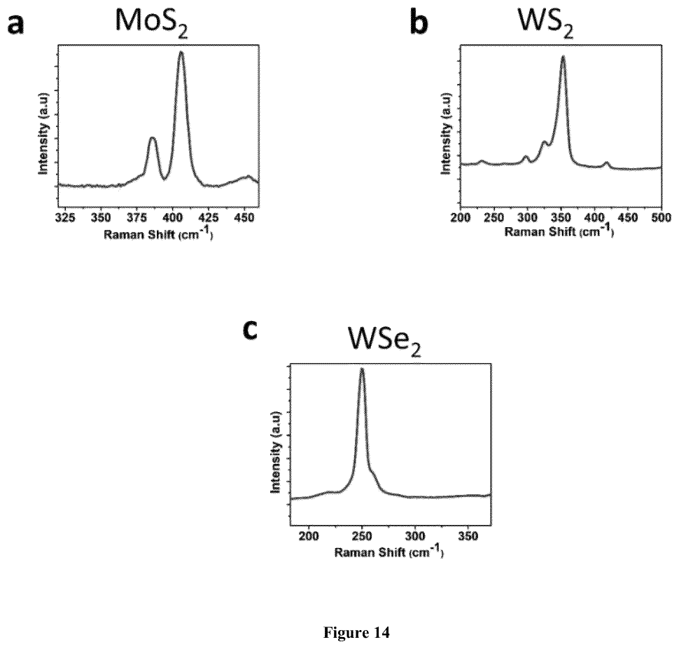

FIG. 11 shows optical images of MoS2, WS2, and WSe2 TMDs monolayers synthesized using sodium silicate as the growth promoter for shorter growth time on 300 nm SiO2 on Si substrate. FIG. 12 represents Photoluminescence spectra of MoS2, MoSe2, WS2, and WSe2 TMDs monolayers synthesised and FIG. 13 compares the PL of monolayer and bilayer WS2 synthesized using sodium silicate as the growth promoter. FIG. 14 represents Raman spectra of MoS2. WS2, and WSe2 TMDS synthesized using sodium silicate as the growth promoter.

### ADVANTAGES OF THE PRESENT DISCLOSURE

The present disclosure provides a process for synthesis of transition metal dichalocogenide (TMD) monolayers that uses a cheap, easy to handle and commonly available material, sodium silicate, as an excellent growth promoter for growing TMD monolayers of high opto-electric quality using atmospheric pressure chemical vapor deposition.

The present disclosure provides a process for synthesis of transition metal dichalocogenide (TMD) monolayers using sodium silicate which is highly effective in significantly enhancing the growth by improving tolerance to subtle changes in growth parameters that could adversely affect the synthesis. It is much more effective than commonly used growth promoters like NaCl.

A skilled artisan will appreciate that the quantity and type of each ingredient can be used in different combinations or singly. All such variations and combinations would be falling within the scope of present disclosure.

The foregoing examples are merely illustrative and are not to be taken as limitations upon the scope of the invention. Various changes and modifications to the disclosed embodiments will be apparent to those skilled in the art. Such changes and modifications may be made without departing from the scope of the invention.

1. A process for the conformal growth of transition metal dichalocogenide (TMD) monolayers on surfaces, textured or smooth, using sodium silicate as a growth promoter, the said process comprises the steps of:
spin coating a dilute solution of a growth promoter in water onto a substrate wherein sodium silicate acts as a growth promoter of transition metal dichalocogenide (TMD) monolayers;
loading the sodium silicate-coated substrate along with the transition metal precursors and chalcogens like elemental sulphur or selenium into the chemical vapour deposition (CVD) chamber;
providing inert gases selected from N2, Ar, H2, or combinations thereof as carrier gases for TMD synthesis;
heating the CVD chamber to the desired reaction temperature and holding the reaction temperature for the synthesis of TMD, which is deposited as TMD monolayers over the sodium silicate-coated substrate; and
cooling the CVD chamber to room temperature to obtain the sodium silicate-coated substrate comprising the TMD monolayers.

2. The process of claim 1, wherein the concentration of growth promoter can be between 0.05%-50% with an optimal coating used is 0.5% of sodium silicate.

3. The process of claim 1, wherein the spin coating is done between 1000-10,000 r.p.m and the optimal speed used is 4000 r.p.m.

4. The process of claim 1, wherein the transition metal precursors are selected from the group consisting of transition metal oxides, chlorides, elemental metal or any other vaporizable form of the transition metal.

5. The process of claim 1, wherein the transition metal precursors are selected from the group consisting of tungsten (W) and molybdenum (Mo).

6. The process of claim 1, wherein the TMD monolayers comprise MoS₂, MoSe₂, WS₂, WSe₂, or a combination thereof.

7. The process of claim 1, wherein the carrier gas for the synthesis of MoS₂ and WS₂ is argon or nitrogen.

8. The process of claim 1, wherein the carrier gas for the synthesis of MoSe₂ and WSe₂ is a mixture of argon and 10% hydrogen.

9. The process of claim 1, wherein the CVD is atmospheric pressure chemical vapour deposition (APCVD).

10. The process of claim 1, wherein the substrate of interest is a semiconductor substrate selected from the group consisting of silicon, doped or undoped, or an active layer of a silicon-on-insulator (SOI) substrate or insulators like Sapphire, Quartz, F-mica, and the like.

11. The process of claim 1, wherein the chalcogens are heated separately in the temperature range of 150° C. to 300° C. by placing the same just outside the furnace for the supply of chalcogens during the reaction.

12. The process of claim 1, wherein the chalcogens are selected from the group consisting of sulphur, selenium, or combinations thereof.

13. The process of claim 8, wherein the heating for chalcogen is set at 200° C. for sulphur and 300° C. for selenium, wherein the heating is turned on 5 min before the target temperature is attained and is turned off after the reaction.

14. The process of claim 1, wherein the deposition of the transition metal dichalocogenide monolayers on the surface of the substrate is carried out at desired reaction temperature of 500° C. to 900° C., wherein the temperature is ramped up at a rate of 5° C./min till the reaction temperature is attained and maintained for 10 min to get scattered triangles and 20 min to get continuous films.

15. The process of claim 1, wherein the process further comprises the step of flushing the tubes of single zone furnace with argon gas at 500 Standard cubic centimetres per minute (sccm) for 5 min and maintaining a constant flow rate of flow rate of 30 sccm for MoS₂ or WS₂ deposition and 200 sccm for WSe₂ or MoSe₂ monolayer deposition throughout the reaction.

16. The process of claim 1, wherein the sodium silicate-coated substrate is positioned in such a way that sodium silicate-coated smooth side facing down in the quartz tube of the single zone furnace for depositing monolayers of WS₂ or WSe₂ synthesized at 850 deg C.

17. The process of claim 1, wherein the sodium silicate-coated substrate is positioned in such a way that sodium silicate-coated side facing down in the quartz tube of the single zone furnace for depositing monolayers of MoS₂ synthesized at 500 deg C. and silicate-coated smooth side facing up for depositing monolayers of MoS₂ synthesized at 600 deg C.

18. The process of claim 1, wherein the sodium silicate-coated substrate is positioned in such a way that sodium silicate-coated side facing up on a separate boat downstream for depositing monolayers of MoS₂ and MoSe₂ synthesized at 700 deg C. or higher.
